(19) United States
(12) Patent Application Publication
(10) Pub. No.: US 2025/0253263 A1
(43) Pub. Date: Aug. 7, 2025

(54) MANUFACTURING METHOD OF SEMICONDUCTOR DEVICE AND SEMICONDUCTOR SUBSTRATE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Kenichi ITANO, Sanda Hyogo (JP); Tsutomu KIYOSAWA, Himeji Hyogo (JP); Hiroshi KONO, Himeji Hyogo (JP); Katsuhisa TANAKA, Himeji Hyogo (JP)

(21) Appl. No.: 19/191,945

(22) Filed: Apr. 28, 2025

Related U.S. Application Data
(63) Continuation of application No. PCT/JP2023/041454, filed on Nov. 17, 2023.

(30) Foreign Application Priority Data
Jul. 31, 2023 (JP) 2023-125124

(51) Int. Cl. H01L 23/544; H01L 21/04

(52) U.S. Cl. CPC H01L 23/544; H01L 21/0475; H01L 2223/54426

(57) ABSTRACT

In a manufacturing method of a semiconductor device according to the present embodiment, there is formed a first mark that is concave from a first direction substantially perpendicular to a first face of an SiC substrate and surrounded by first and third sides extending in a second direction orthogonal to the first direction on the first face and second and fourth sides extending in a third direction orthogonal to the first and second directions, and includes at least one recessed pattern recessed in the third direction from the first side toward the third side opposite to the first side on the first side. An SiC layer is epitaxially grown on the first mark of the SiC substrate.

### CROSS REFERENCE TO RELATED APPLICATIONS

This application is based upon and claims the benefit of priority from the prior Japanese Patent Application No. 2023-125124 filed on Jul. 31, 2023 and International Patent Application PCT/JP2023/041454 filed on Nov. 17, 2023 the entire contents of which are incorporated herein by reference.

### FIELD

The embodiments of the present invention relate to a manufacturing method of a semiconductor device and a semiconductor substrate.

### BACKGROUND

Silicon carbide (SiC) has high insulation breakdown field strength and low on resistance since it has a wide bandgap in comparison with silicon. Therefore, a SiC semiconductor has been developed as a material of power semiconductor elements for electric power.

When semiconductor elements are formed on an SiC substrate, a mark such as an alignment mark is needed. An SiC epitaxial layer may be grown on a surface of an SiC substrate after a mark is formed on the SiC substrate. At this time, a specific crystal face called “facet” appears on the SiC epitaxial layer, and the mark on the SiC substrate is blurred and looks deformed in its image. This makes it difficult to identify the mark in the image in each process and pattern alignment and the like may become difficult.

### BRIEF DESCRIPTION OF THE DRAWINGS

FIG. 1 is a plan view illustrating a configuration example of a silicon carbide (SiC) substrate according to a first embodiment;

FIG. 2 is a plan view illustrating an example of marks according to the first embodiment;

FIG. 3 is a plan view illustrating a configuration example of one mark;

FIG. 4 is a sectional view taken along a line 4-4 in FIG. 2;

FIG. 5 is a sectional view of an SiC substrate according to a comparative example;

FIG. 6 is a diagram illustrating an image of marks with facets;

FIG. 7 is a diagram illustrating an image of marks without facets;

FIG. 8 is a sectional view illustrating an example of a manufacturing method of a semiconductor device according to the first embodiment;

FIG. 9 is a plan view illustrating a configuration example of a mark according to a second embodiment;

FIG. 10 is a plan view illustrating a plurality of marks;

FIG. 11 is a plan view illustrating a configuration example of marks according to a third embodiment;

FIG. 12 is a plan view illustrating a configuration example of marks according to a fourth embodiment;

FIG. 13 is a plan view illustrating a configuration example of marks according to a fifth embodiment; and

FIG. 14 is a plan view illustrating a configuration example of marks according to a sixth embodiment.

### DETAILED DESCRIPTION

Embodiments will now be explained with reference to the accompanying drawings. The present invention is not limited to the embodiments. In the present specification and the drawings, elements identical to those described in the foregoing drawings are denoted by like reference characters and detailed explanations thereof are omitted as appropriate.

In a manufacturing method of a semiconductor device according to the present embodiment, there is formed a first mark that is concave from a first direction substantially perpendicular to a first face of an SiC substrate and surrounded by first and third sides extending in a second direction orthogonal to the first direction on the first face and second and fourth sides extending in a third direction orthogonal to the first and second directions, and includes at least one recessed pattern recessed in the third direction from the first side toward the third side opposite to the first side on the first side. An SiC layer is epitaxially grown on the first mark of the SiC substrate.

### First Embodiment

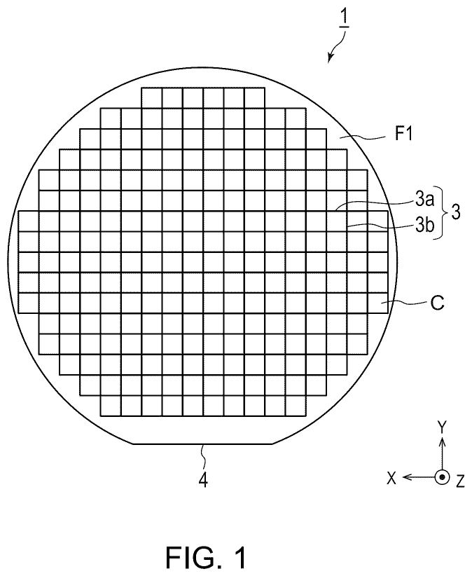

FIG. 1 is a plan view illustrating a configuration example of a silicon carbide (SiC) substrate according to a first embodiment. An SiC substrate 1 is an example of a semiconductor substrate. The SiC substrate 1 is, for example, an n-type silicon carbide monocrystal substrate made of four-layer periodic hexagonal crystal (4H-SiC) of silicon carbide. The SiC substrate 1 can be used as a semiconductor substrate of a power semiconductor device for electric power such as a Schottky barrier diode, a MOSFET (Metal Oxide Semiconductor Field Effect Trasistor), a PN diode, an IGBT (Insulated Gate Bipolar Transistor), and a GTO (Gate Turn-Off thyristor).

The SiC substrate 1 includes a first face F1. Dicing lines 3 are provided on the first face F1 of the SiC substrate 1 to divide the substrate into a plurality of semiconductor chips C. The dicing lines 3 are positions planned to be cut in a dicing process. By cutting the SiC substrate 1 along the dicing lines 3, the semiconductor chips C are divided into individual pieces. The dicing lines 3 include, for example, dicing lines 3a extending in an X direction parallel to an orientation flat 4, and dicing lines 3b extending in a Y direction orthogonal to the X direction.

In the semiconductor chip C, semiconductor elements (not illustrated) may be provided and a pattern in the middle of manufacturing may be provided.

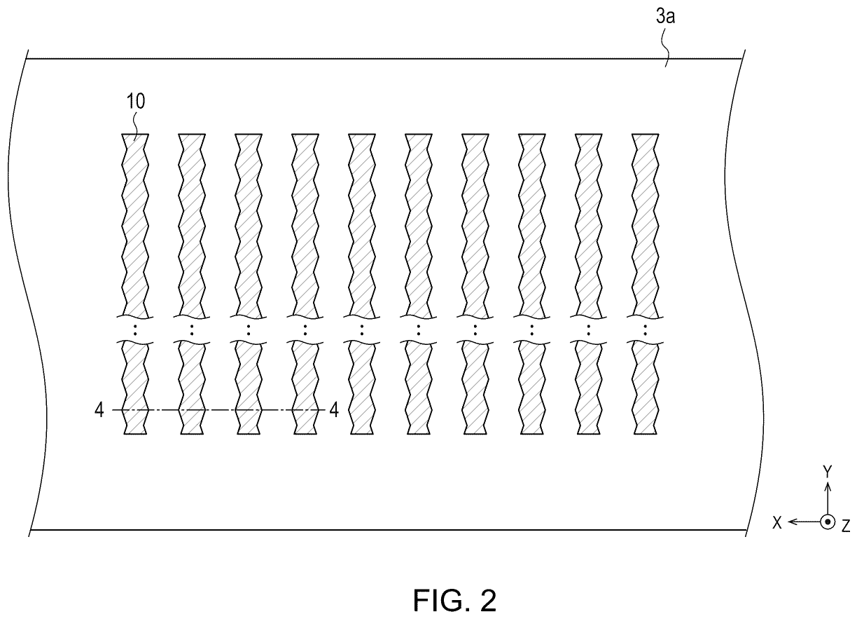

FIG. 2 is a plan view illustrating an example of marks according to the first embodiment. Marks 10 are marks provided on the dicing lines 3a on the first face F1 of the SiC substrate 1. The marks 10 may be alignment marks to be used for alignment in processing of the SiC substrate 1 in a semiconductor manufacturing process. A semiconductor manufacturing apparatus such as an exposure device to be used in a lithography process aligns the SiC substrate 1 by automatically recognizing the marks 10. In a case where the marks 10 are not clearly recognized, the semiconductor manufacturing apparatus cannot automatically align the substrate by using an image of the marks 10, and cannot manufacture a semiconductor device or may cause a defect.

The marks 10 are arranged at predetermined second intervals in the X direction. Each mark 10 extends in the Y direction. The mark 10 is configured to be concavo-convex in a Z direction (a first direction) substantially perpendicular to the first face F1. For example, the mark 10 is formed into a groove having a concave shape by etching the first face F1 of the SiC substrate 1 from the Z direction.

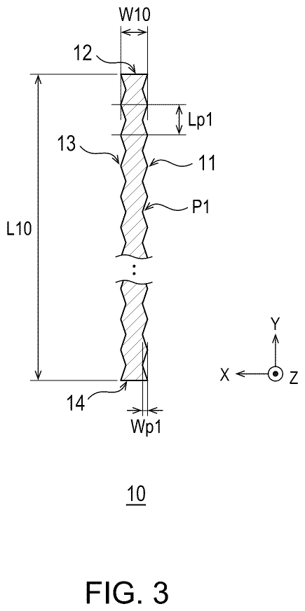

FIG. 3 is a plan view illustrating a configuration example of one mark. The mark 10 is a narrow and long mark including a first side 11, a second side 12, a third side 13, and a fourth side 14. The mark 10 is surrounded by the first to fourth sides 11 to 14 in a planar view from the Z direction. The first side 11 and the third side 13 are long sides extending in the Y direction (the second direction) orthogonal to the Z direction. The third side 13 is a side opposite to the first side 11. The second side 12 and the fourth side 14 are short sides extending in the X direction (the third direction) orthogonal to the Z direction and the Y direction. The fourth side 14 is a side opposite to the second side 12. The first and third sides 11 and 13 are longer than the second and fourth sides 12 and 14.

The first and third sides 11 and 13 have a plurality of recessed patterns P1 recessed in the X direction in a planar view from the Z direction. The recessed patterns P1 on the first side 11 are patterns recessed in a direction from the first side 11 toward the third side 13 in a planar view from the Z direction, and the recessed patterns P1 on the third side 13 are patterns recessed in a direction from the third side 13 toward the first side 11 in a planar view from the Z direction. The recessed patterns P1 are recessed (constricted) in the X direction from the lengths of the second and fourth sides 12 and 14 (maximum widths of the mark 10 in the X direction), and periodically repeatedly appear in the Y direction on the first and third sides 11 and 13.

For example, it is assumed that a length (a width) W10 of the second and fourth sides 12 and 14 is, for example, approximately 6 μm, and a length (a length of the mark 10 in the Y direction) L10 of the first and third sides 11 and 13 is, for example, approximately 50 μm. In this case, the recessed patterns P1 periodically repeatedly appear with a length Lp1 in the Y direction on the first and third sides 11 and 13. The length Lp1 is, for example, 1 μm to 2 μm. Each recessed pattern P1 is formed of two inclined sides inclined with respect to the Y direction or the X direction. Therefore, the first and third sides 11 and 13 consist not of sides parallel to the Y direction but of inclined sides with respect to the Y direction. Accordingly, the first and third sides 11 and 13 consist of sides inclined with respect to the Y direction and are processed zigzag in a planar view from the Z direction.

A recess width Wp1 of the recessed pattern P1 in the X direction is less than ½ of the length of the second and fourth sides 12 and 14. For example, on the assumption that the length of the second and fourth sides 12 and 14 is approximately 6 μm, the recess width Wp1 of the recessed pattern P1 is less than 3 μm. Accordingly, the marks 10 are not separated in the Y direction, but are connected continuously.

The marks 10 illustrated in FIG. 2 respectively have a configuration illustrated in FIG. 3.

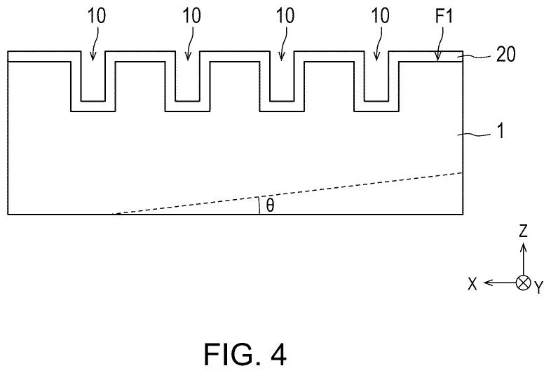

FIG. 4 is a sectional view taken along a line 4-4 in FIG. 2. The mark 10 is a groove processed in the Z direction on the first face F1 of the SiC substrate 1. Due to the marks 10, the first face F1 is configured into a concavo-convex shape. An SiC epitaxial layer 20 is provided on the marks 10 provided on the SiC substrate 1. The SiC epitaxial layer 20 covers side surfaces and bottom surfaces of the marks 10 and also covers the first face F1.

Here, in a section perpendicular to the Y direction, the first face F1 is inclined at an angle θ in a <11-20> direction from a (0001) crystal face of the SiC substrate 1. However, the slope of the first face F1 is not limited to the slope in this direction, and may be inclined in a different direction. The angle θ is called “off angle” of the SiC substrate 1. The off angle θ is, for example, 8 degrees or less, and is specifically 4 degrees. The SiC substrate having the off angle is also called “off-angle substrate”. A 35 direction (a +X direction) descending the slope of the off angle θ as the third direction is also called “upstream side of the off direction”. A direction (a −X direction) ascending the slope of the off angle θ as a direction opposite to the third direction is also called “downstream side of the off direction”.

According to the first embodiment, the first and third sides 11 and 13 of the mark 10 have the recessed patterns P1 in a planar view from the Z direction. Accordingly, even when the SiC substrate 1 has the off angle θ, the SiC epitaxial layer 20 can be formed with a substantially uniform film thickness on the marks 10 and the first face F1.

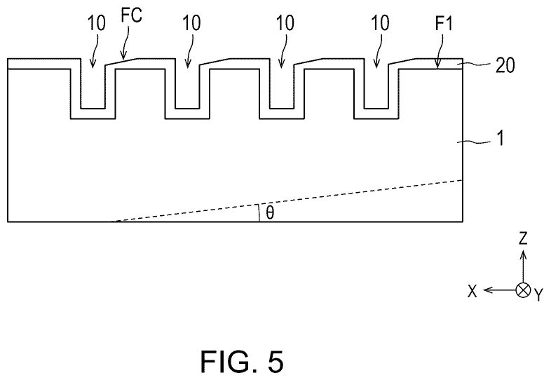

In a case where the first and third sides 11 and 13 of the mark 10 do not have the recessed patterns P1 in a planar view from the Z direction, but have linear shapes parallel to the Y direction, a crystal face called “facet” is formed on the SiC epitaxial layer 20. For example, FIG. 5 is a sectional view of an SiC substrate according to a comparative example. In this comparative example, first and third sides 11 and 13 of a mark 10 are formed into linear shapes parallel to the Y direction in a planar view from the Z direction. In this case, a facet FC occurs at an upper end portion of the groove of the mark 10 depending on the off angle θ of the SiC substrate 1.

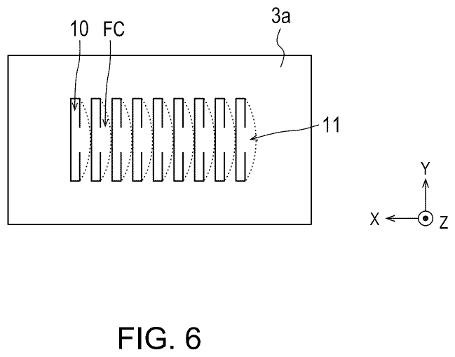

FIG. 6 is a diagram illustrating an image of marks with facets. A facet FC has occurred on the first side 11 of the mark 10. In this case, as illustrated in FIG. 6, the image of the first side 11 is blurred and unclear. Therefore, the semiconductor manufacturing apparatus may not be able to automatically recognize the marks 10.

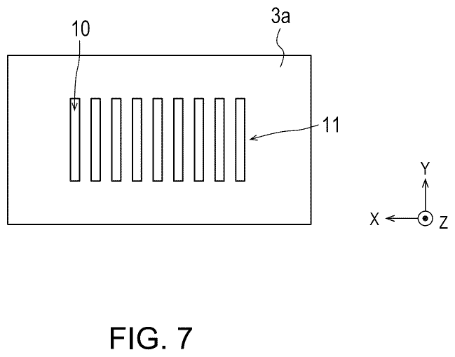

Meanwhile, FIG. 7 is a diagram illustrating an image of marks without facets. In the first embodiment, the first and third sides 11 and 13 of the mark 10 have recessed patterns P1 in a planar view from the Z direction. Since the SiC substrate 1 is an off-angle substrate, slight facets have occurred on the SiC epitaxial layer 20. However, the facets are small and hardly noticeable. In this case, as illustrated in FIG. 7, images of the first and third sides 11 and 13 are not blurred but clear. Accordingly, the semiconductor manufacturing apparatus can automatically recognize the marks 10. As a result, it becomes easy to align the patterns in each process.

Next, a manufacturing method of a semiconductor device according to the first embodiment is described.

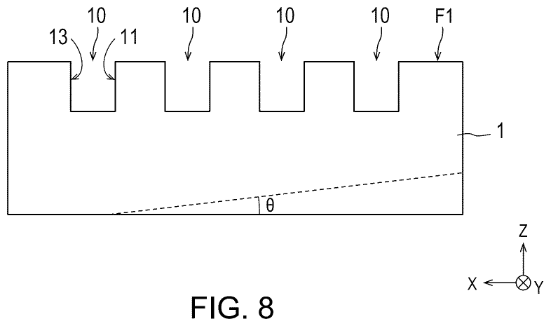

FIG. 8 is a sectional view illustrating an example of the manufacturing method of a semiconductor device according to the first embodiment.

The first face F1 of the SiC substrate 1 having an off angle θ is processed by using an etching technique such as a lithography technique or an RIE (Reactive Ion Etching) method. The off angle θ is, for example, 4 degrees. Accordingly, grooves of the marks 10 are formed on the first face F1 of the SiC substrate 1. The configuration of the marks 10 in a planar view from the Z direction is as described above with reference to FIGS. 2 and 3.

Next, the SiC epitaxial layer 20 is formed on the first face F1 of the SiC substrate 1 by using an epitaxial growth method. At this time, as illustrated in FIGS. 2 and 3, the mark 10 includes the recessed patterns P1 in a planar view from the Z direction. Accordingly, the SiC epitaxial layer 20 is formed with a substantially uniform film thickness on the marks 10 and the first face F1, and facets are suppressed. Accordingly, the SiC epitaxial layer 20 illustrated in FIG. 4 is obtained.

Thereafter, in the region of the semiconductor chip C in FIG. 1, semiconductor elements are formed on the SiC substrate 1 or the SiC epitaxial layer 20. The semiconductor elements are power semiconductor elements for electric power such as a Schottky barrier diode, a MOSFET, a PN diode, an IGBT, and a GTO.

After semiconductor elements are formed on the SiC substrate 1 or the SiC epitaxial layer 20, the SiC substrate 1 is diced into semiconductor chips C in a dicing process. The marks 10 are used as alignment marks or the like for alignment in processing of the SiC substrate 1 in each semiconductor manufacturing process, and are formed on the dicing lines 3. Therefore, the marks 10 are cut together with the dicing lines 3 in the dicing process.

A diced semiconductor chip C is mounted on a different substrate or the like and packaged. Accordingly, the semiconductor device according to the first embodiment is completed.

In the first embodiment, the mark 10 includes the recessed patterns P1 in a planar view from the Z direction. Accordingly, even when the SiC substrate 1 is an off-angle substrate, facets on the SiC epitaxial layer 20 are suppressed to be unnoticeable. In this case, images of the first and third sides 11 and 13 become clear, and the semiconductor manufacturing apparatus can automatically recognize the marks 10. As a result, pattern alignment and the like can be easily performed in each process.

### Second Embodiment

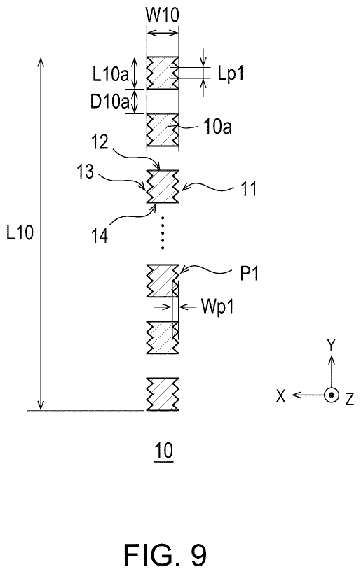

FIG. 9 is a plan view illustrating a configuration example of a mark according to a second embodiment. The mark 10 according to the second embodiment is formed of a plurality of partial marks 10a each having a first length L10a and arranged at first intervals D10a in the Y direction. The first interval D10a is, for example, 4 μm. The first length L10a is, for example, 4 μm. The width W10 is, for example, 4 μm. The first interval D10a, the first length L10a, and the width W10 are not limited thereto.

Each partial mark 10a includes the first side 11, the second side 12, the third side 13, and the fourth side 14. Each partial mark 10a is surrounded by the first to fourth sides 11 and 14 in a planar view from the Z direction. The first side 11 and the third side 13 are sides extending in the Y direction. The third side 13 is a side opposite to the first side 11. The second side 12 and the fourth side 14 are sides extending in the X direction. The fourth side 14 is a side opposite to the second side 12.

The first and third sides 11 and 13 have a plurality of recessed patterns P1 recessed in the X direction in a planar view from the Z direction. The recessed patterns P1 are recessed (constricted) in the X direction from the lengths of the second and fourth sides 12 and 14 (maximum widths of the mark 10 in the X direction), and periodically repeatedly appear in the Y direction on the first and third sides 11 and 13.

For example, the recessed patterns P1 periodically repeatedly appear with a length of 1 μm to 2 μm in the Y direction on the first and third sides 11 and 13. Accordingly, the first and third sides 11 and 13 are processed zigzag with respect to the Y direction in a planar view from the Z direction.

Each recessed pattern P1 is formed of two inclined sides inclined with respect to the Y direction or the X direction as in the first embodiment. Therefore, the first and third sides 11 and 13 consist not of sides parallel to the Y direction but of inclined sides.

The recess width Wp1 of the recessed patterns P1 in the X direction is less than ½ of the length of the second and fourth sides 12 and 14. For example, on the assumption that the length of the second and fourth sides 12 and 14 is approximately 4 μm, the recess width Wp1 of the recessed patterns P1 is less than 2 μm. Accordingly, the partial marks 10a themselves are continuously connected in the Y direction.

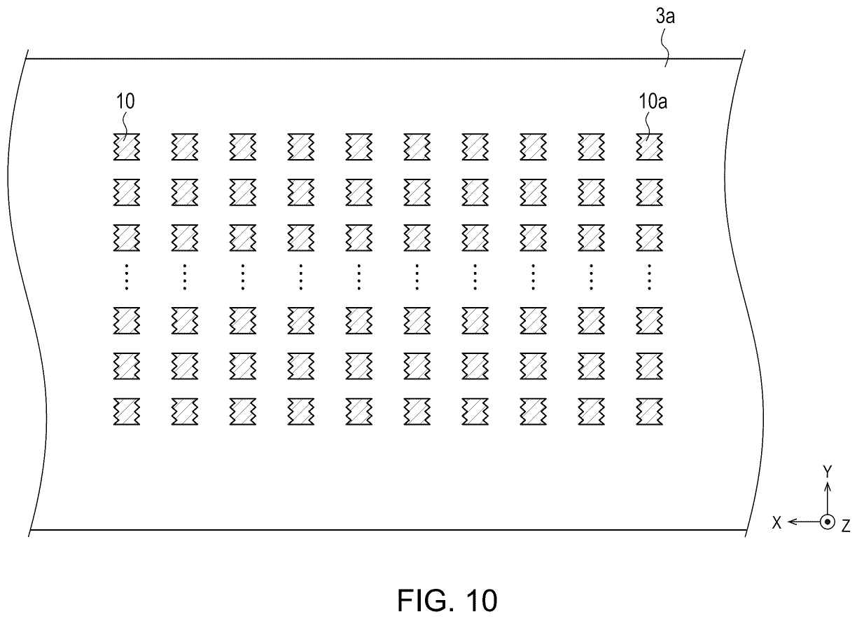

FIG. 10 is a plan view illustrating a plurality of marks. In the second embodiment, the marks 10 respectively have the configuration illustrated in FIG. 9. Accordingly, as illustrated in FIG. 10, the partial marks 10a are two-dimensionally arranged on the first face F1. That is, the partial marks 10a are two-dimensionally arranged like dots in a planar view from the Z direction.

Even with this configuration, when the SiC substrate 1 is an off-angle substrate, facets on the SiC epitaxial layer 20 are suppressed to be unnoticeable. Therefore, images of the first and third sides 11 and 13 of the marks 10 according to the second embodiment become clear, and the semiconductor manufacturing apparatus can automatically recognize the marks 10. Accordingly, the second embodiment can attain effects identical to those of the first embodiment. The marks 10 according to the second embodiment can be manufactured in the same manner as in the first embodiment by changing the mask pattern in lithography.

### Third Embodiment

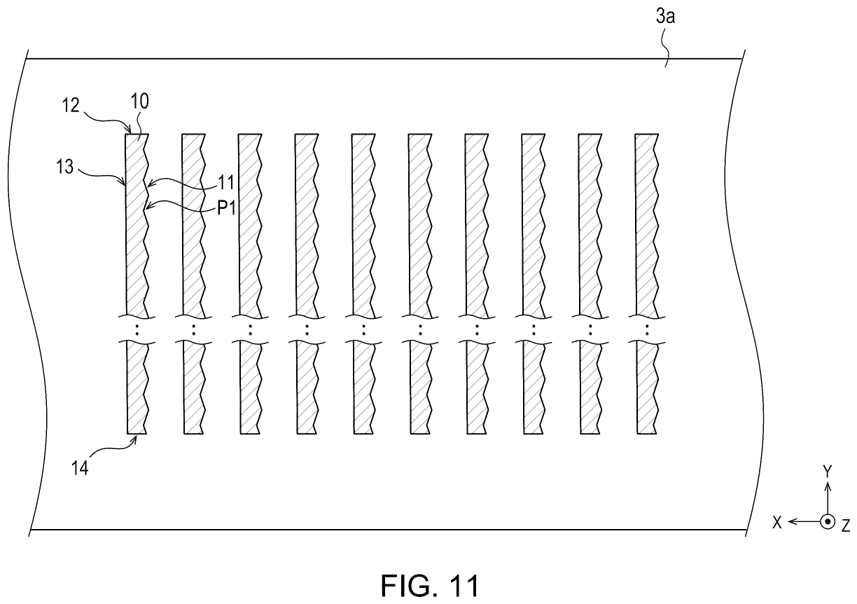

FIG. 11 is a plan view illustrating a configuration example of marks according to a third embodiment. In the mark 10 according to the third embodiment, recessed patterns P1 are provided on the first side 11, but are not provided on the third side 13. The first side 11 is one side of two sides 11 and 13 of the mark 10, which depends on an inclination direction of a (0001) crystal face of the SiC substrate 1 illustrated in FIG. 8. That is, when the first face F1 of the SiC substrate 1 in FIG. 8 is made horizontal, the recessed patterns P1 are formed on the side 11 present in a direction ascending the (0001) crystal face (a dashed line in FIG. 8) of the SiC substrate 1. It is assumed that the first face F1 of the SiC substrate 1 is inclined at 4 degrees in a <11-20> direction of the SiC substrate 1 from the (0001) crystal face of the SiC substrate 1.

For example, on the assumption that the off angle θ is an acute angle as illustrated in FIG. 8, when the first face F1 is made horizontal, the marks 10 repeat concavities and convexities toward a direction ascending a slope of the (0001) crystal face of the SiC substrate 1 (a substantially-X direction: a downstream side in an off direction). In this direction (the substantially-X direction) ascending the slope of the (0001) crystal face of the SiC substrate 1, facets of the SiC epitaxial layer 20 are easily noticeable on the first side 11 rising from a bottom surface of the groove of the mark 10 toward the first face F1 out of the first and third sides 11 and 13.

Therefore, in the third embodiment, on the assumption that the off angle θ is an acute angle as illustrated in FIG. 8, the recessed patterns P1 are formed on the first side 11 on which the mark 10 rises in the direction ascending the slope of the (0001) crystal face of the SiC substrate 1 (the substantially-X direction). Accordingly, facets on the SiC epitaxial layer 20 are effectively suppressed to be unnoticeable.

In a direction descending the slope of the (0001) crystal face of the SiC substrate 1 (a substantially +X direction: an upstream side in the off direction), although the third side 13 rising from the bottom surface of the groove of the mark 10 to the first face F1 is linear, facets on the SiC epitaxial layer 20 are unnoticeable. Therefore, the recessed patterns P1 do not have to be formed on the third side 13.

Even with this configuration, images of the first and third sides 11 and 13 of the mark 10 become clear, and the semiconductor manufacturing apparatus can automatically recognize the marks 10. Accordingly, the third embodiment can attain effects identical to those of the first embodiment. Further, the mark 10 according to the third embodiment can be manufactured in the same manner as in the first embodiment by changing the mask pattern in lithography.

### Fourth Embodiment

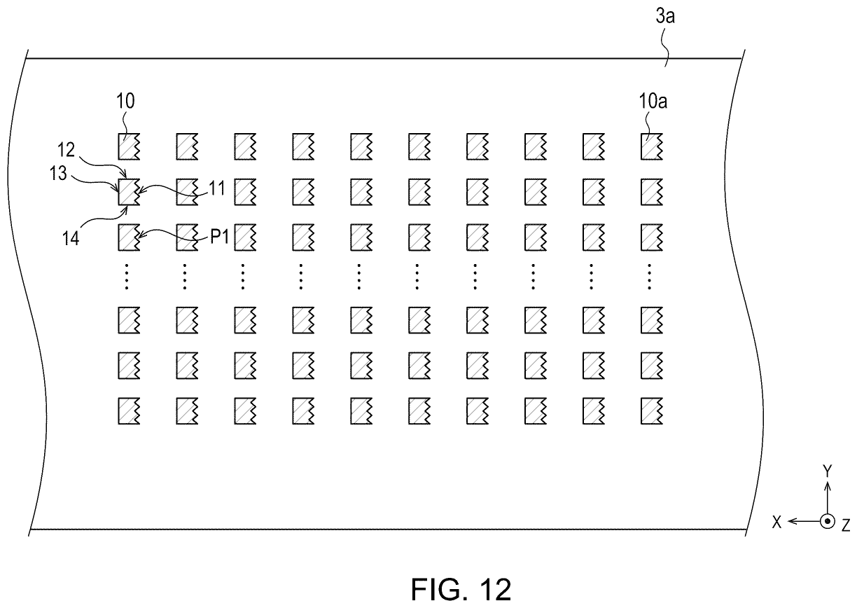

FIG. 12 is a plan view illustrating a configuration example of marks according to a fourth embodiment. The fourth embodiment is a combination of the second embodiment and the third embodiment. Therefore, in the fourth embodiment, a plurality of partial marks 10a are two-dimensionally arranged like dots in a planar view from the Z direction. The arrangement of the partial marks 10a may be the same as that in the second embodiment.

Each partial mark 10a includes recessed patterns P1 on the first side 11 as with the mark 10 of the third embodiment, but the recessed patterns P1 are not provided on the third side 13. The first side 11 has been formed on one side of the two sides 11 and 13 of the partial marks 10a, which depends on an inclination direction of the (0001) crystal face of the SiC substrate 1.

For example, in the fourth embodiment, on the assumption that the off angle θ is an acute angle as in FIG. 8, the recessed patterns P1 are formed on the first side 11 on which the mark 10 has risen in the direction (the substantially-X direction) ascending the slope of the (0001) crystal face of the SiC substrate 1. Accordingly, facets on the SiC epitaxial layer 20 are effectively suppressed to be unnoticeable.

In the direction (the substantially +X direction) descending the slope of the (0001) crystal face of the SiC substrate 1, although the third side 13 on which the mark 10 has risen is linear, facets of the SiC epitaxial layer 20 are unnoticeable. Therefore, the recessed patterns P1 do not have to be formed on the third side 13.

Even with this configuration, images of the first and third sides 11 and 13 of the mark 10 become clear, and the semiconductor manufacturing apparatus can automatically recognize the marks 10. Accordingly, the fourth embodiment can attain effects identical to those of the first embodiment. Further, the mark 10 according to the fourth embodiment can be manufactured in the same manner as in the first embodiment by changing the mask pattern in lithography.

### Fifth Embodiment

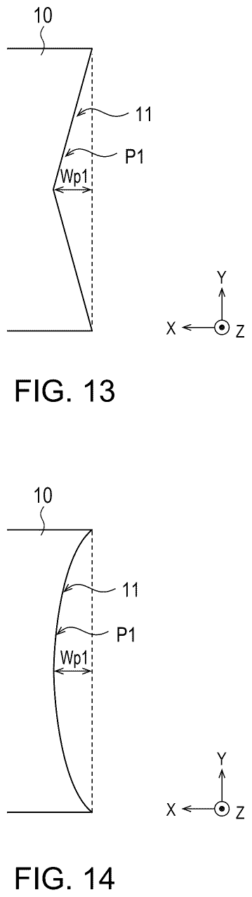

FIG. 13 is a plan view illustrating a configuration example of a mark according to a fifth embodiment. In each mark 10 according to the fifth embodiment, one recessed pattern P1 is provided on the first side 11 in a planar view from the Z direction. The recessed pattern P1 is formed of two straight lines inclined with respect to the Y direction in a planar view from the Z direction. The two straight lines constituting the recessed pattern P1 are inclined so as to be recessed toward the center of the mark 10 in the X direction at the center of the mark 10 in the Y direction. The number of recessed patterns P1 to be provided on the first side 11 is not limited to any number.

It suffices that the recess width Wp1 of the recessed pattern P1 in the X direction is set substantially equal to the width of a facet in the X direction which occurs on the SiC epitaxial layer 20. Accordingly, image blurring caused by the facet can be canceled.

As described above, a facet on the SiC epitaxial layer 20 on the first side 11 can be suppressed to be unnoticeable even in the fifth embodiment.

### Sixth Embodiment

FIG. 14 is a plan view illustrating a configuration example of a mark according to a sixth embodiment. In each mark 10 according to the sixth embodiment, one recessed pattern P1 is provided on the first side 11 in a planar view from the Z direction. The recessed pattern P1 is formed into a substantially arc shape in a planar view from the Z direction. An arc of the recessed pattern P1 is formed to be recessed toward the center of the mark 10 in the X direction at the center of the mark 10 in the Y direction. In this manner, the shape of the recessed pattern P1 to be provided on the first side 11 may be formed of a curve.

It suffices that the recess width Wp1 of the recessed pattern P1 in the X direction is set substantially equal to the width of a facet in the X direction which occurs on the SiC epitaxial layer 20. Accordingly, image blurring caused by the facet can be canceled.

As described above, a facet on the SiC epitaxial layer 20 on the first side 11 can be suppressed to be unnoticeable even in the sixth embodiment.

The fifth and sixth embodiments may be applied to the second or fourth embodiment. That is, the first side 11 of the partial marks 10a may include one recessed pattern P1.

### Notes

(1)

A manufacturing method of a semiconductor device comprising:
forming a first mark concave from a first direction substantially perpendicular to a first face of an SiC substrate and surrounded by first and third sides extending in a second direction orthogonal to the first direction on the first face and second and fourth sides extending in a third direction orthogonal to the first and second directions, and including at least one recessed pattern recessed in the third direction from the first side toward the third side opposite to the first side on the first side; and
epitaxially growing an SiC layer on the first mark of the SiC substrate.
   (2)

The method of (1), wherein the first face is inclined in a direction opposite to the third direction from a (0001) crystal face of the SiC substrate.

(3)

The method of (1) or (2), wherein a plurality of the recessed patterns are formed on the first side.

(4)

The method of (1) or (2), wherein a recess width of the recessed pattern in the third direction is less than ½ of a length of the second side.

(5)

The method of any one of (1) to (4), wherein
the first and third sides are sides of the first mark in a longitudinal direction, and
the second and fourth sides are shorter than the first and third sides.
   (6)

The method of any one of (1) to (4), wherein a plurality of the first marks are arranged at a first interval in the second direction.

(7)

The method of any one of (1) to (6), wherein the recessed pattern is formed of a straight line inclined with respect to the second direction in a planar view from the first direction.

(8)

The method of any one of (1) to (6), wherein the recessed pattern has a substantially arc shape in a planar view from the first direction.

(9)

The method of any one of (1) to (8), wherein the first marks are arranged in the second direction or the third direction in a planar view from the first direction.

(10)

The method of (1), wherein the first face is inclined in a <11-20> direction from the (0001) face.

(11)

A semiconductor substrate comprising:
an SiC substrate including a first face, and including a first mark concave in a first direction substantially perpendicular to the first face; and
an SiC epitaxial layer provided on the first mark, wherein
the first mark is surrounded by first and third sides extending in a second direction orthogonal to the first direction on the first face and second and fourth sides extending in a third direction orthogonal to the first and second directions, and includes at least one recessed pattern recessed in the third direction from the first side toward the third side opposite to the first side on the first side.
   (12)

The semiconductor substrate of (11), wherein the first face is inclined in a direction opposite to the third direction from a (0001) crystal face of the SiC substrate.

(13)

The semiconductor substrate of (11) or (12), wherein a plurality of the recessed patterns are formed on the first side.

(14)

The semiconductor substrate of any one of (11) to (13), wherein a recess width of the recessed pattern in the third direction is less than ½ of a length of the second side.

(15)

The semiconductor substrate of any one of (11) to (14), wherein the first and third sides are sides of the first mark in a longitudinal direction, and the second and fourth sides are shorter than the first and third sides.

(16)

The semiconductor substrate of any one of (11) to (15), wherein a plurality of the first marks are arranged at a first interval in the second direction.

(17)

The semiconductor substrate of any one of (11) to (16), wherein the recessed pattern is formed of a straight line inclined with respect to the second direction in a planar view from the first direction.

(18)

The semiconductor substrate of any one of (11) to (16), wherein the recessed pattern has a substantially arc shape in a planar view from the first direction.

(19)

The semiconductor substrate of any one of (11) to (18), wherein the first marks are arranged in the second direction or the third direction in a planar view from the first direction.

(20)

The semiconductor substrate of (11), wherein the first face is inclined in a <11-20> direction from the (0001) face.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A manufacturing method of a semiconductor device comprising:
forming a first mark concave from a first direction substantially perpendicular to a first face of an SiC substrate and surrounded by first and third sides extending in a second direction orthogonal to the first direction on the first face and second and fourth sides extending in a third direction orthogonal to the first and second directions, and including at least one recessed pattern recessed in the third direction from the first side toward the third side opposite to the first side on the first side; and
epitaxially growing an SiC layer on the first mark of the SiC substrate.

2. The method of claim 1, wherein the first face is inclined in a direction opposite to the third direction from a (0001) crystal face of the SiC substrate.

3. The method of claim 1, wherein a plurality of the recessed patterns are formed on the first side.

4. The method of claim 1, wherein a recess width of the recessed pattern in the third direction is less than ½ of a length of the second side.

5. The method of claim 1, wherein
the first and third sides are sides of the first mark in a longitudinal direction, and
the second and fourth sides are shorter than the first and third sides.

6. The method of claim 1, wherein a plurality of the first marks are arranged at a first interval in the second direction.

7. The method of claim 1, wherein the recessed pattern is formed of a straight line inclined with respect to the second direction in a planar view from the first direction.

8. The method of claim 1, wherein the recessed pattern has a substantially arc shape in a planar view from the first direction.

9. The method of claim 1, wherein the first marks are arranged in the second direction or the third direction in a planar view from the first direction.

10. The method of claim 1, wherein the first face is inclined in a <11-20> direction from the (0001) face.

11. A semiconductor substrate comprising:
an SiC substrate including a first face, and including a first mark concave in a first direction substantially perpendicular to the first face; and
an SiC epitaxial layer provided on the first mark, wherein
the first mark is surrounded by first and third sides extending in a second direction orthogonal to the first direction on the first face and second and fourth sides extending in a third direction orthogonal to the first and second directions, and includes at least one recessed pattern recessed in the third direction from the first side toward the third side opposite to the first side on the first side.

12. The semiconductor substrate of claim 11, wherein the first face is inclined in a direction opposite to the third direction from a (0001) crystal face of the SiC substrate.

13. The semiconductor substrate of claim 11, wherein a plurality of the recessed patterns are formed on the first side.

14. The semiconductor substrate of claim 11, wherein a recess width of the recessed pattern in the third direction is less than ½ of a length of the second side.

15. The semiconductor substrate of claim 11, wherein
the first and third sides are sides of the first mark in a longitudinal direction, and
the second and fourth sides are shorter than the first and third sides.

16. The semiconductor substrate of claim 11, wherein a plurality of the first marks are arranged at a first interval in the second direction.

17. The semiconductor substrate of claim 11, wherein the recessed pattern is formed of a straight line inclined with respect to the second direction in a planar view from the first direction.

18. The semiconductor substrate of claim 11, wherein the recessed pattern has a substantially arc shape in a planar view from the first direction.

19. The semiconductor substrate of claim 11, wherein the first marks are arranged in the second direction or the third direction in a planar view from the first direction.

20. The semiconductor substrate of claim 11, wherein the first face is inclined in a <11-20> direction from the (0001) face.
